(19) United States
(12) Patent Application Publication
(10) Pub. No.: US 2018/0298488 A1
(43) Pub. Date: Oct. 18, 2018

(54) FILM FORMATION APPARATUS AND FILM FORMATION METHOD

(71) Applicant: Hitachi Kokusai Electric Inc., Tokyo (JP)

(72) Inventors: Eiji SAKATA, Tokyo (JP); Toshiyuki KIKUCHI, Toyama (JP); Satoru KASHIWAGI, Tokyo (JP); Yasuo SERA, Tokyo (JP)

(21) Appl. No.: 15/510,838

(22) PCT Filed: Sep. 22, 2014
(86) PCT No.: PCT/JP2014/075092

§ 371 Date: Mar. 13, 2017

(51) Int. Cl. C23C 14/52; C23C 16/50; C23C 14/34; H01J 37/34; H01J 37/32; C23C 14/56

(52) U.S. Cl. CPC C23C 14/52; C23C 16/50; C23C 14/34; H01J 2237/24592; H01J 37/32935; C23C 14/562; H01J 37/3277; H01J 37/3476

(57) ABSTRACT

A film formation apparatus is configured so as to be equipped with: a film-forming chamber for forming a thin film using plasma on a substrate at a film formation position; an abnormal discharge-detecting section for detecting an abnormal discharge of the plasma; an imaging device for imaging abnormal plasma, which is the plasma when an abnormal discharge is detected, or an abnormal substrate surface, which is the substrate surface on which a thin film is formed when an abnormal discharge is detected; and a storage unit for storing the images taken by the imaging device.

### TECHNICAL FIELD

The present invention relates to a film formation apparatus and a film formation method of forming a thin film on a substrate using plasma.

### BACKGROUND ART

As a method of forming a thin film on the surface of a substrate, a vapor deposition technique is used for example. The vapor deposition technique is generally classified into PVD (Physical Vapor Deposition) and CVD (Chemical Vapor Deposition). For example, in a case of manufacturing a semiconductor substrate by forming a thin film to a substrate such as a silicon substrate or a glass substrate, a plasma CVD method of applying a plasma processing to the substrate or a sputtering method of applying a sputtering processing to the substrate is used.

In the plasma CVD method, a power supply such as of a direct current or high frequency is used in order to form a desired material gas into a plasma state. Also in the sputtering method, an inert gas is converted into a plasma state in order to form ions for popping out a target material. Accordingly, a power supply such as of direct current or high frequency is used. When the plasma is generated, an ideal plasma cannot always be generated but abnormal discharge of the plasma may be generated sometimes due to the setting position or the state of the electrode and, further, effects of dusts and dirts in the film forming chamber.

For avoiding undesired effect on the film forming processing, by such abnormal plasma discharge, a technique of moderating or inhibiting plasma abnormal discharge by applying a processing of controlling the power supply (lowering or stopping of the power supply) so as not to cause undesired effect on the film formation has been known (prior art literature 1). However, in a case where plasma abnormal discharge occurs, various actual measurements or experiments are necessary, for recognizing whether it is always necessary to moderate or inhibit the abnormal discharge. At present, moderation or inhibition of the plasma abnormal discharge cannot always be considered necessary depending on the level, and it has not yet been considered what effect is caused in the film formation depending on the level of the plasma abnormal discharge.

The plasma CVD method or the sputtering method is sometimes used for forming a thin film on a substrate also in a substrates other than semiconductor substrates, for example, functional film including an optical film, such as polarization film or a retardation film. In the case of the functional film, performance as the function film is necessary but more importance is attached to the visibility when the film is used, for example, being attached to the surface of a touch panel or liquid crystal display (LCD), in which occurrence of a portion such as a black spot or a stain that may hinder the visibility should be prevented.

Heretofore, the functional film is formed in the configuration of a cut sheet but a manufacturing method or a film formation apparatus of transporting a raw material (resin film) on a roll by taking up on the opposite side and applying the film forming processing successively in the take up course is sometimes adopted. In this case, since the visibility cannot be confirmed in the film forming step, the taken-up rolled material is transferred after the completion of the film forming processing to another inspection step for inspection of absence or presence of visibility defects.

There are various causes for visibility defects such as black spots or stains. For example, they are sometimes caused by handling in other processing steps than the film forming step such that they are present already in the stage of starting materials, dusts or dirts are deposited upon re-winding the raw material on another roll for flowing to the film formation step. Further, in the film-forming step, dirts or dusts in the film-forming chamber may be deposited, or abnormal discharge of plasma may occur under the effect of the setting position or the state of the electrode and, further, under the effect of dusts or dirts in the film forming chamber may cause abnormal discharge, thereby causing visibility defects such as black spots or stains.

However, it has not yet been adopted a method of conforming the causal relation as to what abnormal discharge of plasma is generated during film forming process and what is the effect of the abnormal discharge on the film forming processing.

### CITATION LIST

### Patent Literature

Patent Literature 1: JP-A No. 2001-102196

### SUMMARY OF THE INVENTION

### Technical Problem

In order to decrease defects upon forming a thin film on a substrate by using plasma, it is necessary to recognize a causal relation between the defect and the cause of generation thereof. In particular, it is necessary to grasp what causal relation is present between the visibility defect and the abnormal discharge of plasma which is considered to be one of causes for generating defects in the film forming step.

The present invention has been accomplished in view of the foregoing situations and it is an object thereof to enable easy recognition for the state of defects generated in the substrate or the state of abnormal discharge of plasma.

### Solution to Problem

Typical constitutions of a film formation apparatus according to the present invention for solving the subjects described above are as follows. That is,

a film formation apparatus comprising:

a film forming chamber for forming a thin film on a substrate at a film forming position by using plasma,

an abnormal discharge detection unit for defecting abnormal discharge of the plasma,

an imaging device for imaging abnormality plasma which is plasma upon detection of the abnormal discharge or an abnormality substrate surface which is a substrate surface formed with the thin film upon detection of the abnormal discharge, and

a storage unit for storing the image taken by the imaging device.

Further, the typical constitution of the film formation method of the present invention is as described below. That is;

a film formation method comprising:

a thin film forming step of forming a thin film on a substrate by using plasma,

an abnormal discharge detection step of detecting abnormal discharge of the plasma,

an imaging step of imaging abnormality plasma which is plasma upon detection of the abnormal discharge or an abnormality substrate surface which is a substrate surface formed with a thin film upon detection of the abnormal discharge,

a storing step of storing an image taken by the imaging step, and

a display step of displaying the image stored by the storing step.

### Advantageous Effects of Invention

According to the constitution described above, the state of defect generated in the substrate or the state of plasma abnormal discharge can be recognized easily.

### BRIEF DESCRIPTION OF DRAWINGS

FIG. 1 is a configurational view of a film formation apparatus according to an embodiment of the present invention.

FIG. 2 is a view illustrating a film formation method according to an embodiment of the present invention.

FIG. 3 is a view illustrating a timing that a substrate monitoring camera according to a preferred embodiment of the present invention images an abnormality substrate surface.

### DESCRIPTION OF EMBODIMENTS

Embodiments of the present invention are to be described.

### (1) Constitution of a Film Formation Apparatus

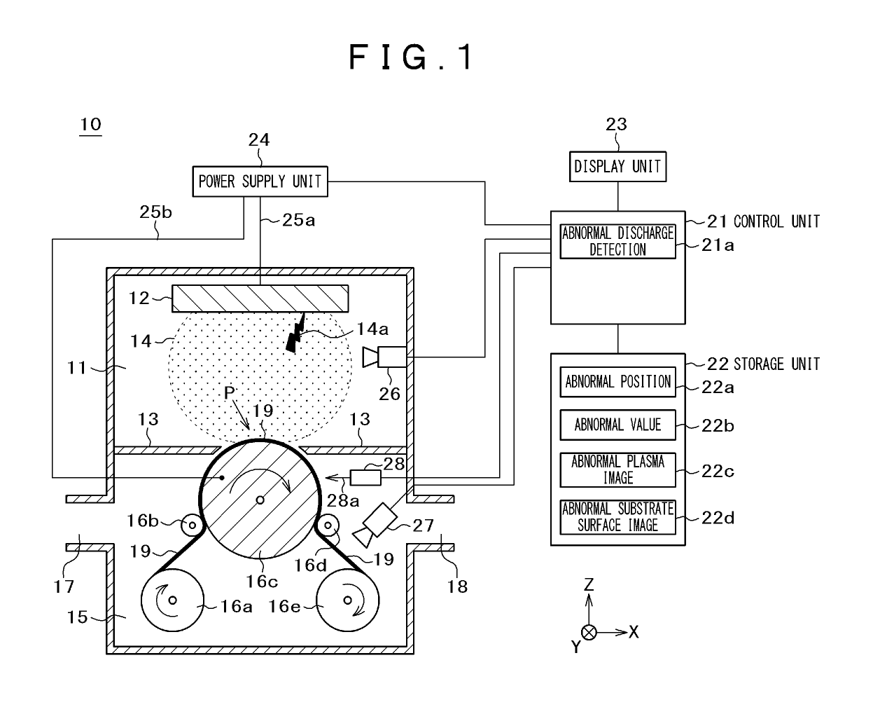

FIG. 1 is a configurational view of a film formation apparatus according to a preferred embodiment of the present invention and illustrates a longitudinal cross sectional view (X-Z cross sectional view of FIG. 1) of a film forming chamber 11. As illustrated in FIG. 1, a film formation apparatus 10 of the preferred embodiment comprises a film forming chamber 11, a substrate accommodation chamber 15, a control unit 21, a storage unit 22, a display unit 23, and a power supply unit 24. In an example of this embodiment, a film formation processing is performed by using a sputtering method to a tape-like substrate 19 in the film forming chamber 11.

In the film forming chamber 11, are provided an electrode 12, a portion of a processing roller 16c, and a plasma monitoring camera 26. The electrode 12 is in a rectangular parallelepiped shape, which forms a cathode as a target. The processing roller 16c is a cylindrical shape having a circular XZ cross section in FIG. 1, which constitutes an anode. The film forming chamber 11 is in a rectangular parallelepiped shape. The direction Y in FIG. 1 is a direction vertical to an XZ plane (direction passing through the paper sheet from the surface to the rear face in FIG. 1).

An electric power is supplied between the electrode 12 and the processing roller 16c from a power supply unit 24 while reducing the pressure in the film forming chamber 11 and introducing an inert gas (for example, argon gas) into the film forming chamber 11. Thus, the argon gas is separated into ions and electrons to generate plasma 14 in the film forming chamber 11. A film forming process of forming a thin film on the surface of the substrate 19 is performed by using the plasma 14. Specifically, ionized argon is collided against a target (electrode 12) and a flicked target material is deposited as a film on the substrate 19 at a film formation position P. The film formation position P is a position where the processing roller 16c is exposed in the film forming chamber 11, which is a position where the substrate 19 is subjected to a film formation process.

A plasma monitoring camera 26 is an imaging device for imaging plasma 14, in particular, imaging abnormal discharge 14a upon abnormal discharge of the plasma 14. The abnormal discharge 14a shown in FIG. 1 is arcing generated between the plasma 14 and the target (electrode 12). The abnormal discharge 14a generates a great amount of particles which may sometime cause visibility defect.

The plasma monitoring camera 26 is connected in view of signals to a control unit 21 based on the instruction from the control unit 11, images the plasma 14 (including abnormal discharge 14a) and sends the taken image (plasma image) to the control unit 21. For example, the plasma monitoring camera 26 receives instruction of a time slot (timing) and an imaging speed (number of imaging shots per one sec) from the control unit 21 and, based on the instruction, images the plasma 14. A method of imaging the plasma 14 (including abnormal discharge 14a) is to be described later.

A substrate accommodation chamber 15 is in a rectangular parallelepiped shape and disposed in adjacent to the film forming chamber 11 via a partitioning wall 13. Rollers 16 for supplying the substrate 19 before film forming processing into the film forming chamber 11 and recovering the substrate 19 after the film forming processing from the inside of the film forming chamber 11, a substrate monitoring camera 27, and a marking device 28 are provided in the substrate accommodation chamber 15. In the example of this embodiment, the substrate 19 is a film formed of a material comprising a tape-like PET (polyethylene terephthalate resin) as a material. A predetermined material is deposited as a film over the substrate 19 to form a known functional film having a sort of function, for example, an anti-reflection film or an ITO (indium Tin Oxide) film, etc.

The rollers 16 include a supply roller 16a, an auxiliary roller 16b, a processing roller 16c, an auxiliary roller 16d, and a recovery roller 16e. Each of the rollers is in a cylindrical shape having a circular XZ cross section in FIG. 1. The supply roller 16a has, wound therearound, a tape-like substrate 19 before film forming processing, rotates in the direction of an arrow shown in the drawing and supplies the substrate 19 to the processing roller 16c. The processing roller 16c is partially exposed in the film forming chamber 11 as described before, rotates in the direction of an arrow in the drawing and performs film-forming processing to the substrate 19 at the exposed position (film forming position P). The recovery roller 16e rotates in the direction of an arrow shown in the drawing and takes up to recover the substrate 19 which has been put to film forming processing by the processing roller 16c. The auxiliary rollers 16b, 16d rotate in the direction opposite to that of the processing roller 16c thereby causing the substrate 19 to be in close contact with the processing roller 16c.

The recovery roller 16e is connected with a rotational driving device (not illustrated) and rotated by the rotational driving device. The rotational driving device is connected in view of signals to the control unit 21 and, based on the instruction from the control unit 21, rotates the recovery roller 16e and while keeping the rotational speed to a predetermined value.

The substrate monitoring camera 27 is an imaging device for imaging the substrate 19, which was at a film forming position P when the plasma 14 generates abnormal discharge, at a position different from the film forming position P after the film forming processing. The substrate monitoring camera 27 is connected in view of signals to the control section 21, images the substrate 19 based on the instruction from the control unit 21, and sends the taken image (image of the substrate surface) to the control unit 21. For example, the substrate monitoring camera 27 receives an instruction such as a time slot (timing) and the imaging speed (number of imaging shots per one sec) from the control unit 21 upon imaging the substrate 19 and images the substrate 19 based on the instruction. The method of imaging the substrate 19 when the plasma 14 generates abnormal discharge is to be described later.

A marking device 28 marks the position of the substrate 19 which was at the film forming position P when the plasma 14 generated abnormal discharge at a position different from the film forming position P after the film forming processing. That is, the marking device 28 is an abnormality detection information addition device of adding an abnormal detection information indicative of abnormality detection to a portion of the substrate 19 which was at the film forming position P upon abnormal discharge of the plasma 14 (for example, end on the surface or the rear face of the substrate 19). The marking device 28 is connected in view of signals to the control unit 21 and marks the substrate 19 based on the instruction from the control unit 21. The marking method when the plasma 14 generates abnormal discharge is to be described later.

The marking device 28 comprises, for example, a known laser processing device of forming a punctuation to the substrate 19 using a laser beam 28a. Of course, the marking device 28 may also be configured with other marking means than the laser processing device.

Further, in the substrate accommodation chamber 15, are provided a gas introduction port 17 for introducing an inert gas (for example, argon gas) into the substrate accommodation chamber 15 and an exhaust port 18 for exhausting the gas in the substrate accommodation chamber 15. The argon gas introduced from the gas introduction port 17 is supplied through a gap between the partitioning wall 13 and the processing roller 16c into the film forming chamber 11 and used for film forming processing. The argon gas, after use for the film forming processing, is returned through the gap between the partitioning wall 13 and the processing roller 16c to the substrate accommodation chamber 15 and discharged through the port 18.

The gas introduction port 17 is connected by way of a gas supply pipe (not illustrated) to a gas supply source (not illustrated). A flow rate control device of controlling the flow rate to a predetermined value (MFC: mass flow controller) is provided to the gas supply pipe. The flow rate control device is connected in view of signals to the control unit 21 and controls the flow rate of the gas flowing through the gas supply pipe, that is, the flow rate of the gas introduced into the substrate accommodation chamber 15 to a predetermined value based on the instruction from the control unit 21.

The exhaust port 18 is connected by way of an exhaust pipe (not illustrated) to an exhaust device (not illustrated) comprising with a vacuum pump. A pressure control device for controlling the pressure in the substrate accommodation chamber 15 to a predetermined value (APC: automatic pressure control valve) is provided to the exhaust pipe. The pressure control device is connected in view of signals to the control unit 21 and controls the pressure in the substrate accommodation chamber 15, that is, the pressure in the film forming chamber 11 to a predetermined value based on the instruction from the central unit 21.

The gas introduction port 17 and the exhaust port 18 may also be configured such that they are provided not in the substrate accommodation chamber 15 but in the film forming chamber 11. Further, they may be configured such that one of the gas introduction port 17 and the exhaust port 18 is provided to the substrate accommodation chamber 15 and the other of them is provided to the film forming chamber 11.

The control section 21 is connected in view of signals with the storage unit 22, the display unit 23, the power supply unit 24, the plasma monitoring camera 26, the substrate monitoring camera 27, the marking device 28, etc., and controls various kinds of processings performed by the film formation apparatus 10. Further, the control unit 21 receives plasma image information or substrate surface image information from the plasma monitoring camera 26 or the substrate monitoring camera 27 and stores the information in the storing unit 22.

Specifically, the control unit 21 controls, for example, such that the flow rate of the argon gas introduced into the substrate accommodation chamber 15 is at a predetermined value and the pressure in the film forming chamber 11 is controlled to a predetermined value. Further, the control section 21 controls the power supply unit 24 such that a voltage applied between the electrode 12 and the processing roller 16c is at a predetermined value. Then, the control unit 21 controls to perform film forming processing of rotating the recovery roller 16e at a predetermined speed to form a thin film on the surface of the substrate 19.

Further, the control unit 21 has an abnormal discharge detection unit 21a for detecting the abnormal discharge 14a of the plasma 14. For example, the abnormal discharge detection unit 21a, in a case of the direct current sputtering method, receives a power supply unit state signal indicative of the level of a power signal outputted from the power supply unit 24 (for example, voltage value) from the power supply unit 24 and detects abnormal discharge 14a based on the level of the power signal. In a case of a radio frequency sputtering, the abnormal discharge detection unit 21a receives, for example, a power supply unit state signal indicative of the level of a reflection wave contained in the high frequency power signal outputted from the power supply unit 24 from the power supply unit 24 and detects the abnormal discharge 14a based on the level of the reflection wave.

As described above, in this embodiment, detection of the abnormal discharge 14a means that the level of the signal in close relation with the abnormal discharge (level of the power signal, level of the reflection wave, etc.) is detected at or more than a predetermined value.

When the abnormal discharge detection unit 21a detects the abnormal discharge 14a, the control unit 21 allows the storage unit 22 to store the abnormal position information 22a indicative of the position of the substrate surface where the thin film is formed upon detection of the abnormal discharge 14a (abnormality substrate surface) in the entire substrate 19 to the storage unit 22. The abnormal position information 22a can be represented, for example, by the distance from the leading position of the tape-like substrate 19, or the transportation time from the start of the rotation of the supply roller 16a to the transportation of the abnormality substrate surface to the film forming position P (that is, a period after the start of the transportation of the substrate 19 to the detection of the abnormal discharge 14a). Since the transportation speed of the substrate 19 is constant, the transportation time indicates the distance.

Further, the control section 21 generates abnormal value information 22b indicative of the state of an abnormality plasma, a plasma 14 when the abnormal discharge 14a is detected upon detection of the abnormal discharge 14a and stores, to the storage unit 22, the abnormal value information 22b and the abnormal plasma image information 22c which is the image information of the abnormality plasma imaged by the plasma monitoring camera 26 in correspondence. The abnormal value information 22b is, for example, the level of the power supply unit state signal detected by the abnormal discharge detection unit 21a, which is, for example, the level of the power signal of the voltage value, etc. and the level of the reflection wave.

Further, the control unit 21 instructs, to the plasma monitoring camera 26, the timing or the imaging speed when imaging the abnormality plasma. Further, the control unit 21 instructs, to the substrate monitoring camera 27, the timing or the imaging speed when imaging the abnormality substrate surface which is the surface of the substrate 19 on which the thin film is formed upon detection of the abnormal discharge 14a.

Further, the control unit 21 causes the substrate monitoring camera 27 to image the abnormality substrate surface at a position different from the film forming position P after detection of the abnormal discharge 14a by the abnormal discharge detection unit 21a based on the abnormal position information 22a described above. Then, the control unit 21 stores, in the storage unit 22, the abnormal position information 22a and the abnormal substrate surface image information 22d which is the image of the abnormality substrate surface in correspondence. Further, the control unit 21 stores, in the storage unit 22, the abnormal position information 22a, the abnormal plasma image information image 22c, and the abnormal substrate surface image information 22d in correspondence to an identical abnormal discharge 14a.

Further, the control unit 21 instructs, to the marking device 28, the timing and the marking position when marking the substrate 19 upon detection of the abnormal discharge 14a. While the marking position is determined based on the abnormal position information 22a described above, it may be a position identical with the position shown by the abnormal position information 22a.

Thus, upon detection of the abnormal discharge 14a, the control unit 21 stores, in the storage unit 22, the abnormal position information 22a indicative of the position of the substrate surface formed with the thin film upon detection of the abnormal discharge 14a, the abnormal value information 22b indicative of the state of the plasma 14 upon detection of the abnormal discharge 14a, the abnormal plasma image information 22c which is the image of the plasma 14 upon detection of the abnormal discharge 14a (abnormality plasma), and the abnormal substrate surface image information 22d which is the image of the substrate surface of the substrate 19 on which the thin film is formed upon detection of the abnormal discharge 14a (abnormality substrate surface) in correspondence.

For example, when first abnormal discharge 14a is detected, the control unit 21 stores, in the storage unit 22, first abnormal position information 22a indicative of the position of the substrate surface on which the thin film is formed upon detection of the first abnormal discharge 14a, first abnormal value information 22b indicative of the state of the plasma 14 upon detection of the first abnormal discharge 14a, first abnormal plasma image information 22c which is the image of the plasma 14 upon detection of the first abnormal discharge 14a (abnormality plasma), and first abnormal substrate surface image information 22d which is an image of the substrate surface of the substrate 19 on which a thin film is formed upon detection of the first abnormal discharge 14a (abnormality substrate surface) in correspondence.

In the same manner, when second abnormal discharge 14a is detected, the control unit 21, while preserving the first abnormal position information 22a, the first abnormal value information 22b, the first abnormal plasma image information 22c, and the first abnormal substrate surface image information 22d as they are, further stores, in the storage unit 22, second abnormal position information 22a, the second abnormal value information 22b, second abnormal plasma image information 22c, and the second abnormal substrate surface image information 22d in correspondence.

Then, the control section 21 combines optional information from the abnormal position information 22a, the abnormal value information 22b, the abnormal image information 22c, and the abnormal substrate image information 22d stored in the storage unit 22 in correspondence, and display the same on the display section 23. For example, combination of the first abnormal value information 22b and the first abnormal plasma image information 22c is displayed. Alternatively, a combination of the first abnormal plasma image information 22c and the first abnormal substrate image information 22d is displayed.

The control unit 21 has a CPU (Central Processing Unit) and a memory for storing an operation program etc. of the control unit 21 as a hard ware constitution, and the CPU operates in accordance with the operation program.

The storage unit 22 stores the abnormal position information 22a, the abnormal value information 22b, the abnormal plasma image information 22c, and the abnormal substrate surface image information 22d described above based on the instruction of the control unit 21.

The display unit 23 displays the abnormal position information 22a, the abnormal value information 22b, the abnormal plasma image information 22c, and the abnormal substrate surface image information 22d stored in the storage unit 22 based on the instruction of the control unit 21.

The power supply unit 24 supplies power between the electrode 12 and the processing roller 16c by way of power supply lines 25a and 25b based on the instruction of the control unit 21. For example, in a case of a direct current sputtering method, a direct current voltage is applied between the electrode 12 and the processing roller 16c. In a case of a high frequency wave sputtering method, a high frequency voltage is applied between the electrode 12 and the processing roller 16c. Further, the power supply unit 24 outputs the power supply unit status signal described above to an abnormal discharge detection unit 21a.

### (2) Film Formation Method

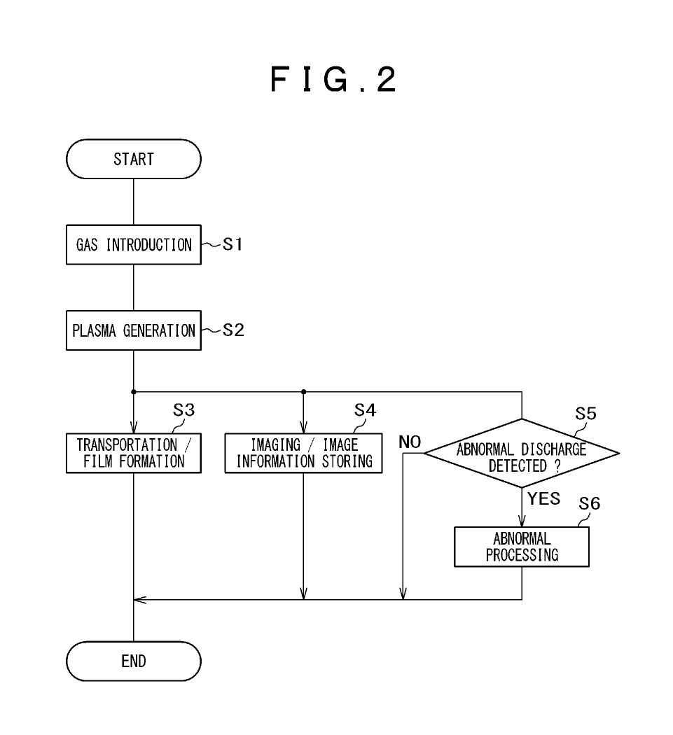

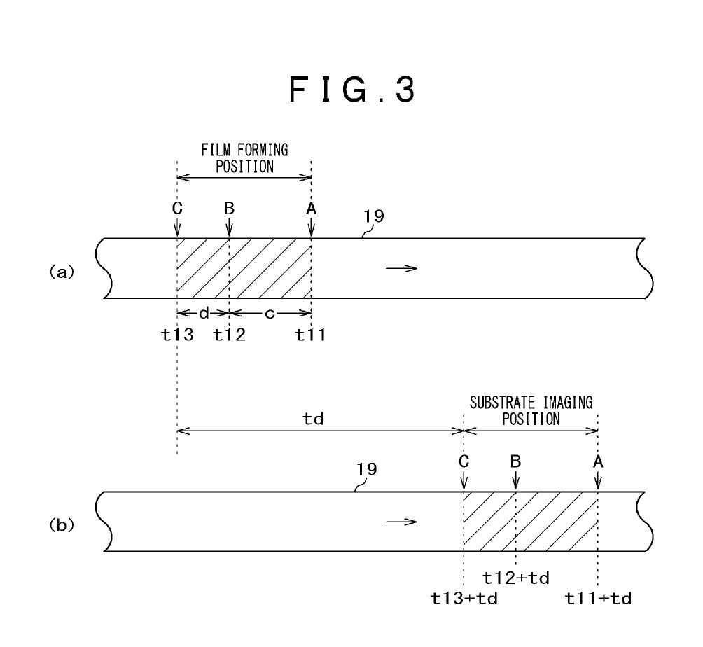

Then, a film formation method of this embodiment is to be described with reference to FIG. 2 and FIG. 3. FIG. 2 is a view illustrating a film formation method according to the embodiment of the present invention and each of the steps of the film formation method is to be described. The film formation method is performed, for example, as a step of functional film manufacturing process by using the film formation apparatus 10 described above. In the following description, the operation of each of the units constituting the film formation apparatus 10 is controlled by the control unit 21.

FIG. 3 is a view illustrating a timing that a substrate monitoring camera according to the embodiment of the present invention images an abnormality substrate surface. FIG. 3(a) illustrates positions A, B, and C of the substrate 19 at the film forming position. An arrows in the substrate 19 shows the transporting direction of the substrate 19 at the film forming position. FIG. 3(b) illustrates the positions A, B, and C, when the substrate 19 is transported from the film forming position for a time td and reaches the substrate imaging position. For example, assuming the time as t11 when the substrate 19 is at the position A of the film forming position, the time when the substrate imaging position is at the position A of the substrate imaging position is (t11+td). In the same manner, assuming the time at the position B of the film forming position as t12, the time of the substrate erasing position at the position B is (t12+td). Assuming the time of the film forming position at the position C as t13, the time of the substrate imaging position at the position C is (t13+td).

### (Gas Introduction Step (Step S1))

First, as illustrated in FIG. 2, while introducing an argon gas from the gas introduction port 17 to the substrate accommodation substrate 15, the gas is exhausted from the exhaustion port 18. In this process, it is controlled such that the introduction amount of the argon gas is at a predetermined flow rate and the pressure in the substrate accommodation chamber 15 (that is, pressure in the film forming chamber 11) is at a predetermined pressure (pressure lower than the atmospheric pressure).

### (Plasma Generation Step (Step S2))

After the pressure in the film forming chamber 11 reaches a predetermined pressure, a voltage is applied from the power supply unit 24 between the electrode 12 and the processing roller 16c to generate a plasma 14 in the film forming chamber 11.

### (Transportation, Film Forming Step (Step S3)

After generation the plasma 14, the recovery roller 16e is driven to start transportation of the substrate 19. The substrate 19 is transported from the supply roller 16a by way of the processing roller 16c to the recovery roller 16e and taken up there. Thus, a thin film is formed continuously on the surface of the substrate 19 during transportation at the film forming position P in the film forming chamber 11.

### (Imaging/Image Information Storing Step (Step S4))

In this process, in parallel with the transportation and film forming step S3, the plasma 14 and the substrate surface as the surface of the substrate 19 are respectively imaged continuously during transportation of the substrate 19. Then, the respective image information are sent continuously to the control unit 21 and are stored continuously by the control unit 21 in the storage unit 22. In this process, the plasma image information as the image information of the plasma 14 is stored in the storage unit 22 in correspondence with the substrate surface image information which is the image information of the substrate surface of the substrate 19 present at the film forming position P upon imaging of the plasma 14 and the position information of the substrate 19 present at the film forming position P upon imaging of the plasma 14.

For example, when it takes a time td for the substrate 19 to be transported from the film forming position P to the imaging position of the substrate monitoring camera 27, the plasma image information imaged at the time t0 and the substrate surface image information imaged at the time (t0+td) are stored in correspondence with the position information of the substrate 19 (distance and the transportation time from the leading position of the tape-like substrate 19), in the storage unit 22.

The plasma image information, the substrate surface image information, and the position information of the substrate 19 thus stored are deleted from the storage unit 22 after predetermined time when the abnormal discharge 14a of the plasma 14 is not detected. Deletion of the information means to put the storage unit 22 into a state where the control unit 21 cannot readout the information and this also includes a case where the information remains physically in the storage unit 22.

### (Abnormal Discharge Detection Step (Step S5))

In parallel with the transportation/film forming step S3, it is judged in the abnormal discharge detection step S5 whether the abnormal discharge 14a of the plasma 14 is detected or not.

### (Abnormality Processing Step (Step S6))

When abnormal discharge 14a is detected in the abnormal discharge detection step S5, an abnormality processing step S6 is performed in parallel with the transportation and film forming step S3.

In the abnormality processing step S6, the marking device 28 marks the position of the substrate 19 present at the film forming position P upon detection of the abnormal discharge 14a to the substrate 19.

For example, the marking device 28 perforates a position of the substrate 19 by a laser light 28a at the surface or the rear face of the end of the substrate 19 (end in the direction Y in FIG. 1). Since the marking is performed on every detection of abnormal discharge 14a, marking easy to distinguish individual abnormal discharge 14a is preferred. For example, marking indicating the detection order of abnormal discharge 14a (for example, marking of number) is preferred. This can easily recognize what abnormal discharge 14a is shown by the marking.

Further, in the abnormality processing step S6, abnormal position information 22a indicative of the position of the substrate 19 where the thin film is formed at the film forming position P upon detection of the abnormal discharge 14a, abnormal value information 22b indicative of the state of the plasma 14 upon detection of the abnormal discharge 14a, abnormal plasma image information 22c which is the image of the plasma 14 upon detection of the abnormal discharge 14a, and an abnormal substrate surface image information 22d which is an image of the substrate 19 on which the thin film is formed at the film forming position P upon detection of the abnormal discharge 14a are stored, in correspondence in the storage unit 22 and displayed on the display unit 23.

Further, in the abnormality processing step S6, the plasma image information for a period within a predetermined range before and after the abnormal discharge detection time which is the time upon detection of the abnormal discharge 14a is not deleted but preserved as the abnormal plasma image information 22c in the storage unit 22 and the plasma image information for the period other than the predetermined range described above is deleted. For example, the plasma image information for the period within the predetermined range before and after the abnormal discharge detection time is transferred as the abnormal plasma image information 22c to a preservation area of the storage unit 22.

For example, when the abnormal discharge 14a is detected at the time t2, the plasma image information for the period within the predetermined range before the abnormal discharge detection time t2 (a: t1 to t2) and for the period within a predetermined range after the abnormal discharge detection time t2 (b: t2 to t3) are not deleted but preserved in the storage unit 22 and the plasma image information for the period other than t1 to t3 are deleted. a and b may be identical or different each other.

Further, as illustrated in FIG. 3, in the abnormality processing step S6, the image information at the position B in the substrate surface of the substrate 19 on which the thin film is formed upon detection of the abnormal discharge 14a, that is, the substrate surface image information within predetermined range (A to C) before and after the image information of the abnormality substrate surface B is not deleted but preserved as the abnormal substrate surface image information 22d in the storage unit 22, and the substrate surface image information other than the predetermined range (A to C) described above are deleted. For example, the substrate surface image information within a predetermined range before and after the abnormality substrate surface is transferred as the abnormal substrate surface image information 22d to the preservation area of the storage unit 22.

For example, upon detection of the abnormal discharge 14a at the time t12, the image information of the substrate surface (A to B) on which the thin film is formed in a period of a predetermined range before the abnormal discharge detection time t12 (c: t11 to t12) and the image information of the substrate surface (B to C) on which the thin film is formed in a period within a predetermined range after the abnormal discharge detection time t12 (d: t12 to t13), that is, the image information of the substrate surface (A to C) on which the thin film is formed for the period t11 to t13 are not deleted but preserved in the storage unit 22, and the image information of the substrate surface on which the thin film is formed for the period other than t11 to t13 are deleted. c and d may be identical or different each other.

The substrate monitoring camera 27 cannot image the abnormality substrate surface (substrate surface on which the thin film is formed at the film forming position P upon detection of the abnormal discharge 14a) at the abnormal discharge detection time t12 and images the abnormality substrate surface at a timing later by the time td than the abnormal discharge detection time t12. td is a period in which when the substrate 19 is transported from the film forming position P to the position of the substrate monitoring camera 27. Accordingly, as illustrated in FIG. 3, when the abnormal discharge 14a is detected at the time t12, the substrate surface image information imaged by the substrate monitoring camera 27 for the period (t11+td) to (t13 +td) are not deleted but preserved in the storage unit 22, and the substrate surface image information imaged by the substrate monitoring camera 27 for the period other than (611+td) to (t11+td) are deleted.

For example, when the first abnormal discharge 14a is detected at the time t12, the first plasma image for the period (t1 to t3) is left and the plasma image for the period other than (t1 to t3) is deleted. Further, the first substrate surface image which is the image of the substrate surface within a predetermined range before and after the abnormality substrate surface at the time t2 are preserved and the substrate surface image other than the predetermined range are deleted. Here, t1<t2<t3.

Then, when second abnormal discharge 14a is detected at the time t12, the second plasma image for the period (t11 to t13) and the first plasma images are preserved and other plasma image is deleted. Further, the second substrate surface image which are the image of the substrate surface within a predetermined range before and after the abnormality substrate surface at the time t12 and the first substrate surface image are preserved and other substrate surface images are deleted. Here, t11<t12<t13.

Thus, after performing the film forming processing for the tape-like substrate 19 for a predetermined period or predetermined length, the transportation and film forming step S3 is completed.

This embodiment provides at least the following effects.
(a) Since it is configured to images and store the abnormality plasma upon detection of the abnormal discharge, or the abnormality substrate surface on which the thin film is formed upon detection of the abnormal discharge, the abnormality plasma or abnormality substrate surface can be confirmed subsequently.
(b) Since it is configured to continuously take and store the image for a period before the detection of abnormal discharge and after the detection of abnormal discharge, and preserve the plasma image for the first period before and after the time upon detection of the abnormal discharge and delete the plasma image for the period other than the first period in a case where the taken image is plasma, whereas preserve the substrate surface image for a second range before and after the abnormality substrate surface and delete the substrate surface image other than the second range in the continuously taken substrate surface images in a case where the taken image is a substrate surface, the plasma or the substrate surface before and after the abnormal discharge can be confirmed subsequently.
(c) Since it is configured to use a substrate on which a thin film is formed during transportation, store abnormal position information indicative of the position of the abnormality substrate surface in the substrate upon detection of abnormal discharge and image the abnormality substrate surface based on the abnormal position information at a first position different from the film forming position, the abnormality substrate surface can be imaged reliably without exposure to the plasma. Further, also in a case where the imaging device of the abnormality substrate surface cannot be provided in the film forming chamber, the abnormality substrate surface can be imaged.
(d) Since it is configured to use a substrate on which the thin film is formed during transportation, store the abnormal position information indicative of the position of the abnormality substrate surface, to the substrate, upon detection of the abnormal discharge, and add the abnormal detection information indicative of detection of abnormal discharge by the abnormal detection information addition device (marking device) indicative of the detection of the abnormal discharge at a second position different from the film forming position to the substrate based on the abnormal position information, the abnormal detection information addition device is not exposed to the plasma, and the position of the abnormality substrate surface can be confirmed easily.
(e) Since it is configured to image the abnormality substrate surface at a first position different from the film forming position based on the abnormal detection information added to the substrate, the abnormality substrate surface can be imaged reliably and easily.
(f) Since it is configured to store the abnormal value information indicative of the stage of the abnormality plasma and the image of the abnormality plasma in correspondence, relation between the abnormal value and the state of abnormality plasma can be recognized.
(g) Since it is configured to supply the tape-like substrate before film forming processing to the film forming chamber, provide the substrate accommodation chamber for recovering the tape-like substrate after film forming processing from the film forming chamber in adjacent to the film forming chamber, and provide the abnormal detection information addition device in the substrate accommodation chamber, film formation to the abnormal detection information addition device can be suppressed. Further, also in a case where the abnormal detection information addition device cannot be provided in the film forming chamber, the abnormal detection information can be added to the substrate.
(h) Since it is configured to provide the substrate surface imaging device in the substrate accommodation chamber, film formation to the substrate surface imaging device can be suppressed. Further, also in a case where the substrate surface imaging device cannot be provided in the film forming chamber, the abnormality substrate surface can be imaged.
(i) Since it is configured to provide the plasma imaging device for imaging the abnormality plasma and the abnormality substrate surface imaging device for imaging the abnormal substrate surface and store the image of the abnormality plasma and the image of the abnormality substrate surface imaged to an identical abnormal discharge in correspondence, the relation between the state of abnormality plasma and the state of the abnormality substrate surface can be recognized.
(j) Since it is configured to display the image of the abnormality plasma and the image of the abnormality substrate surface in correspondence, the relation between the state of the abnormality plasma and the state of the abnormality substrate surface can be confirmed visually.

It is apparent that the present invention is not restricted to the embodiments described above but can be modified variously within a range not departing the gist thereof.

In the embodiment described above, the abnormal discharge detection unit 21a has configured to detect the abnormal discharge 14a based on the level of the power signal outputted from the power supply unit 24 or the level of the reflection wave. However, it may also be configured such that the abnormal discharge detection unit 21a detects the generation of the abnormal discharge 14a by imaging the plasma causing the abnormal discharge 14a and receiving the image of the taken abnormal discharge 14a from the plasma monitoring camera 26. The abnormal discharge detection unit 21a can also be configured to detect the generation of the abnormal discharge 14a, for example, by comparison between normal plasma and plasma upon abnormal discharge.

Alternatively, it may also be configured such that an optical sensor for detecting emission due to the abnormal discharge 14a is provided in the film forming chamber 11 and an abnormal discharge detection signal from the optical sensor is received by the abnormal discharge detection unit 21a to detect the abnormal discharge 14a. Alternatively, an electromagnetic wave sensor for detecting electromagnetic waves due to abnormal discharge 14a may be provided in the film forming chamber 11, and the abnormal discharge detection signal from the electromagnetic sensor is received by the abnormal discharge detection unit 21a to detect the abnormal discharge 14a.

Further, in the embodiment described above, the film formation apparatus has been configured so as to form the thin film by using the sputtering method but the present invention is not restricted only thereto. For example, the film formation apparatus can be configured so as to form a thin film by using a plasma CVD method. When the plasma CVD method is used, it is preferred to provide a permeation window to the film forming chamber 11, dispose the plasma monitoring camera 26 to the outside of the film forming chamber 11 to image the plasma through the permeation window by the plasma monitoring camera 26. The embodiment described above may also be configured such that the permeation window is provided to the film forming chamber 11, the plasma monitoring camera 26 is disposed to the outside of the film forming chamber 11 and plasma is imaged by way of the permeation window by the plasma monitoring camera 26.

Further, in the embodiment described above, the film has been formed under a reduced pressure but the present invention is applicable not only under a reduced pressure but also under an atmospheric pressure depending on the species of the film to be formed. In a case of film formation under the atmospheric pressure, an ink-jet device of discharging a liquid ink may also be used as the marking device 28.

Further, the embodiment described above has been configured so as to image and store continuously before the detection of the abnormal discharge and after the detection of the abnormal discharge, preserve the image of the plasma or the substrate surface within a predetermined range before and after the time upon detection of abnormal discharge and delete the image other than the predetermined range. However, it may also be configured to preserve the image for the plasma and the substrate surface within one of predetermined ranges before and after the time upon detection of abnormal detection and delete the image in other than the predetermined range.

Further, in the embodiment described above, the laser fabrication device as the marking device 28 has been provided in the substrate accommodation chamber 15, but it may also be configured to provide a permeation window in the substrate accommodation chamber dispose, the laser fabrication device is provided to the outside of the substrate accommodation chamber 15, and emits the laser fabrication device a laser beam by way of the permeation window. Further, it may be also configured to provide a permeation window in the film forming chamber 11, dispose the laser fabrication device to the outside of the film forming chamber 11, and irradiate the laser beam by the laser fabrication device by way of the permeation window.

Further, in the embodiment described above, the tape-like resin film has been used as the substrate, but wafers, for example, as silicon substrate or glass substrate, etc. can also be used as the substrate.

Further, the present invention can be assessed not only as the apparatus or the method of performing the processing of the present invention but also can be recognized, for example, as a program for realizing such a method or a recording medium for storing the program.

### LIST OF REFERENCE SIGNS

10: Film forming apparatus
11: Film forming chamber
12: Electrode (cathode)
13: Partition wall
14: Plasma
14a: Abnormal discharge
15: Substrate accommodation chamber
16: Roller
16a: Supply roller
16b: Auxiliary roller
16c: Processing roller (anode)
16d: Auxiliary roller
16e: Recovery roller
17: Gas introduction port
18: Exhaust port
19: Substrate
21: Control unit
21a: Abnormal discharge detection unit
22: Storage unit
22a: Abnormal position storage unit
22b: Abnormal value storage unit
22c: Abnormal plasma image storage unit
22d: Abnormal substrate surface image storage unit
23: Display unit (monitor)
24: Power supply unit
25a: Power supply line
25b: Power supply line
26: Plasma monitoring camera (imaging device)
27: Substrate monitoring camera (imaging device)
28: Marking device (abnormal detection information addition device)
28a: Laser beam

1. A film formation apparatus comprising:
a film forming chamber for forming a thin film on a substrate at a film forming position by using plasma,
an abnormal discharge detection unit for detecting abnormal discharge of the plasma,
an imaging device for imaging abnormality plasma which is plasma upon detection of the abnormal discharge or an abnormality substrate surface which is a substrate surface formed with the thin film upon detection of the abnormal discharge, and
a storage unit for storing the image taken by the imaging device, wherein
the substrate is formed with the thin film during transportation,
the storage unit stores an abnormal position information indicative of the position of the abnormality substrate surface in the substrate upon detection of the abnormal discharge,
the imaging device includes a substrate surface imaging device for imaging the abnormality substrate surface, and
the substrate surface imaging device images the abnormality substrate surface at a first position different from the film forming position based on the abnormal position information.

2.-3. (canceled)

4. A film formation apparatus comprising:
a film forming chamber for forming a thin film on a substrate at a film forming position by using plasma,
an abnormal discharge detection unit for detecting abnormal discharge of the plasma,
an imaging device for imaging abnormality plasma which is plasma upon detection of the abnormal discharge or an abnormality substrate surface which is a substrate surface formed with the thin film upon detection of the abnormal discharge, and
a storage unit for storing the image taken by the imaging device, wherein
the substrate is formed with the thin film during transportation,
the storage unit stores an abnormal position information indicative of the position of the abnormality substrate surface in the substrate upon detection of the abnormal discharge, and the apparatus has
an abnormal detection information addition device of adding abnormal position information indicative of the detection of the abnormal discharge to the substrate at a second position different from the film forming position based on the abnormal position information.

5. The film formation apparatus according to claim 4, wherein
the imaging device includes a substrate surface imaging device for imaging the abnormality substrate surface, and
the substrate surface imaging device images the abnormality substrate surface at a first position different from the film forming position, based on the abnormality detection information added to the substrate.

6. (canceled)

7. The film formation apparatus according to claim 4, wherein
a substrate accommodation chamber that supplies a tape-like substrate before film forming processing to the film forming chamber and recovers the tape-like substrate after film forming processing from the film forming chamber is provided in adjacent with the film forming chamber, and
the abnormality detection information addition device is provided in the substrate accommodation chamber.

8. The film formation apparatus according to claim 7, wherein
the imaging device includes a substrate surface imaging device for imaging the abnormality substrate surface and
the substrate surface imaging device is provided in the substrate accommodation chamber.

9.-19. (canceled)

20. The film formation apparatus according to claim 1, wherein
the imaging device continuously takes image for a period before detection of the abnormal discharge and after detection of the abnormal discharge, and
the storage unit preserves a plasma image in a first period before and after the time upon detection of the abnormal discharge and deletes a plasma image in other period than the first period in the continuously taken image in the continuously taken image in a case where the taken image is that of the plasma and
preserves a substrate surface image within a second range before and after the abnormality substrate surface and deletes the substrate surface image other than the second range in the substrate surface image taken continuously in a case where the taken image is that of the substrate surface.

21. The film formation apparatus according to claim 1, wherein
the imaging device includes a plasma imaging device imaging the abnormality plasma,
the abnormal discharge detection unit generates abnormal value information indicative of the state of the abnormality plasma, and
the storage unit stores the abnormal value information and the image of abnormality plasma in correspondence.

22. The film formation apparatus according to claim 8, wherein
the imaging device includes both a plasma imaging device for imaging the abnormality plasma and a substrate surface imaging device for imaging the abnormality substrate surface, and
the storage unit stores the image of the abnormality plasma and the image of the abnormality substrate surface imaged for an identical abnormal discharge in correspondence.

23. The film formation apparatus according to claim 22, wherein
the apparatus includes a display unit of displaying an image taken by the imaging device, and
the display unit displays the image of the abnormality plasma and the image of the abnormality substrate surface stored in the storage unit in correspondence.

24. The film formation apparatus according to claim 1, wherein
the imaging device includes both a plasma imaging device for imaging the abnormality plasma and a substrate surface imaging device for imaging the abnormality substrate surface, and
the storage unit stores the image of the abnormality plasma and the image of the abnormality substrate surface imaged for an identical abnormal discharge in correspondence.

25. The film formation apparatus according to claim 4, wherein
the imaging device includes both a plasma imaging device for imaging the abnormality plasma and a substrate surface imaging device for imaging the abnormality substrate surface, and
the storage unit stores the image of the abnormality plasma and the image of the abnormality substrate surface imaged for an identical abnormal discharge in correspondence.

26. The film formation apparatus according to claim 5, wherein
the imaging device includes both a plasma imaging device for imaging the abnormality plasma and a substrate surface imaging device for imaging the abnormality substrate surface, and
the storage unit stores the image of the abnormality plasma and the image of the abnormality substrate surface imaged for an identical abnormal discharge in correspondence.

27. The film formation apparatus according to claim 1, wherein
the imaging device includes both a plasma imaging device for imaging the abnormality plasma and a substrate surface imaging device for imaging the abnormality substrate surface, and
the storage unit stores the image of the abnormality plasma and the image of the abnormality substrate surface imaged for an identical abnormal discharge in correspondence.

28. The film formation apparatus according to claim 7, wherein
the imaging device includes both a plasma imaging device for imaging the abnormality plasma and a substrate surface imaging device for imaging the abnormality substrate surface, and
the storage unit stores the image of the abnormality plasma and the image of the abnormality substrate surface imaged for an identical abnormal discharge in correspondence.

29. The film formation apparatus according to claim 8, wherein
the imaging device includes both a plasma imaging device for imaging the abnormality plasma and a substrate surface imaging device for imaging the abnormality substrate surface, and
the storage unit stores the image of the abnormality plasma and the image of the abnormality substrate surface imaged for an identical abnormal discharge in correspondence.
